(19) United States
(12) Patent Application Publication
(10) Pub. No.: US 2008/0205466 A1
(43) Pub. Date: Aug. 28, 2008

(54) RIDGE WAVEGUIDE LASER WITH A COMPRESSIVELY STRAINED LAYER

(75) Inventors: Ashish K. Verma, San Jose, CA (US); Ola Sjolund, Morgan Hill, CA (US); Charles Blakely Roxlo, Saratoga, CA (US)

Correspondence Address: WORKMAN NYDEGGER, 60 EAST SOUTH TEMPLE, 1000 EAGLE GATE TOWER, SALT LAKE CITY, UT, 84111, US

(73) Assignee: FINISAR CORPORATION, Sunnyvale, CA (US)

(21) Appl. No.: 12/036,146

(22) Filed: Feb. 22, 2008

Related U.S. Application Data
(60) Provisional application No. 60/891,456, filed on Feb. 23, 2007.

(51) Int. Cl. H01S 5/22

(52) U.S. Cl. 372/45.011

(57) ABSTRACT

In one example embodiment, a ridge waveguide (RWG) laser includes a substrate, an active layer disposed above the substrate, a ridge structure disposed above the active layer, a contact layer disposed above the ridge structure, a compressively strained dielectric passivation layer disposed above the active layer and extending along either side of the ridge structure such that the passivation layer is in substantial contact with each side of the ridge structure, and a top metallic contact layer disposed above both the dielectric passivation layer and the contact layer and layered alongside the portions of the dielectric passivation layer that contact the sides of the ridge structure.

### CROSS-REFERENCE TO RELATED APPLICATIONS

The present application claims priority from U.S. Provisional Patent Application Ser. No. 60/891,456, filed Feb. 23, 2007 and entitled “Ridge Waveguide Laser with a Compressively Strained Layer,” which is incorporated herein by reference in its entirety.

### BACKGROUND

Semiconductor ridge waveguide (RWG) lasers are currently used in a variety of technologies and applications, including communications networks. Generally, RWG lasers produce a stream of coherent, monochromatic light by stimulating photon emission from a solid state material. Example RWG laser designs are commonly used in optical transmitters. Optical transmitters convert electrical signals into optical signals for transmission via an optical communication network.

A semiconductor RWG laser generally includes a dielectric passivation layer that covers selected portions of the laser so as to electrically isolate the selected portions from adjacent devices. The dielectric passivation layer also protects selected portions of the laser from harmful environmental factors, such as contamination and humidity. The dielectric passivation layer can also reduce parasitic capacitance in the laser.

Semiconductor RWG lasers also include an active region. During the manufacture and operation of a semiconductor RWG laser, the active region can experience tensile strain that can cause defect formation in the crystal structure of the active region. The ultimate type and magnitude of strain in the active region results from the combination of intrinsic epitaxial strain in the active region lattice and external strain applied by non-epitaxial layers deposited as part of the laser manufacturing process. The magnitude and sign of strain from the epitaxially grown layers is highly controllable, while strain from the non-epitaxially grown layers tends to be less controllable. The defect formation inside the active region caused by tensile strain on the active region can render the laser unusable.

### BRIEF SUMMARY OF SOME EXAMPLE EMBODIMENTS

In general, example embodiments of the present invention relate to ridge waveguide (RWG) lasers with one or more compressively strained layers. In one example embodiment, a RWG laser includes a compressively strained dielectric passivation layer. This compressively strained dielectric passivation layer can be used to counteract other external tensilely strained layers resulting in a no strain or a compressive strain in the active region of the RWG laser.

In one example embodiment, a RWG laser includes a substrate, an active layer disposed above the substrate, a ridge structure disposed above the active layer, a contact layer disposed above the ridge structure, a compressively strained dielectric passivation layer disposed above the active layer and extending along either side of the ridge structure such that the passivation layer is in substantial contact with each side of the ridge structure, and a top metallic contact layer disposed above both the dielectric passivation layer and the contact layer and layered alongside the portions of the dielectric passivation layer that contact the sides of the ridge structure.

In another example embodiment, a transmitter optical sub-assembly includes a barrel and a RWG laser at least partially disposed within the barrel. The barrel defines a port that is configured to optically connect the RWG laser with a fiber-ferrule. The RWG laser includes a substrate, an active layer disposed above the substrate, a ridge structure disposed above the active layer, a contact layer disposed above the ridge structure, a compressively strained dielectric passivation layer disposed above the active layer and extending along either side of the ridge structure such that the passivation layer is in substantial contact with each side of the ridge structure, and a top metallic contact layer disposed above both the dielectric passivation layer and the contact layer and layered alongside the portions of the dielectric passivation layer that contact the sides of the ridge structure.

In yet another example embodiment, an optoelectronic transceiver module includes a printed circuit board, a receiver optical sub-assembly electrically connected to the printed circuit board, and a transmitter optical sub-assembly electrically connected to the printed circuit board. The transmitter optical sub-assembly includes a barrel and a RWG laser at least partially disposed within the barrel. The barrel defines a port that is configured to optically connect the RWG laser with a fiber-ferrule. The RWG laser includes a substrate, an active layer disposed above the substrate, a ridge structure disposed above the active layer, a contact layer disposed above the ridge structure, a compressively strained dielectric passivation layer disposed above the active layer and extending along either side of the ridge structure such that the passivation layer is in substantial contact with each side of the ridge structure, and a top metallic contact layer disposed above both the dielectric passivation layer and the contact layer and layered alongside the portions of the dielectric passivation layer that contact the sides of the ridge structure.

### BRIEF DESCRIPTION OF THE DRAWINGS

To further clarify the above and other aspects of example embodiments of the present invention, a more particular description of these examples will be rendered by reference to specific embodiments thereof which are disclosed in the appended drawings. It is appreciated that these drawings depict only example embodiments of the invention and are therefore not to be considered limiting of its scope. It is also appreciated that the drawings are diagrammatic and schematic representations of example embodiments of the invention, and are not limiting of the present invention nor are they necessarily drawn to scale. Example embodiments of the invention will be disclosed and explained with additional specificity and detail through the use of the accompanying drawings in which:

FIG. 1 is a perspective view of an example optoelectronic transceiver module; and

FIG. 2 is a cross sectional view of an example RWG laser.

### DETAILED DESCRIPTION OF SOME EXAMPLE EMBODIMENTS

In general, example embodiments of the present invention relate to ridge waveguide (RWG) lasers with one or more compressively strained layers. In one example embodiment, a RWG laser includes a compressively strained dielectric passivation layer. This compressively strained dielectric passivation layer can be used to counteract other external tensilely strained layers resulting in no strain or a compressive strain in the active region of the RWG laser. External tensilely strained layers are external to the semiconductor ridge structure, and may comprise either metal or dielectric, such as silicon oxide/nitride, for instance, or metal. In at least some cases, external tensilely strained layers are not crystalline, and are not made of InP or any of its quaternary cousins. The term “strain” as used herein is defined as the deformation of atomic bonds in a semiconductor crystal lattice structure. Examples of strain include, but are not limited to, stretching and compression of atomic bonds. Although strain is generally a local property which may vary in the ridge region of the RWG laser, the net overall strain of a ridge region may be determined using a wafer bow measurement or other measurement techniques.

### 1. Example Operating Environment

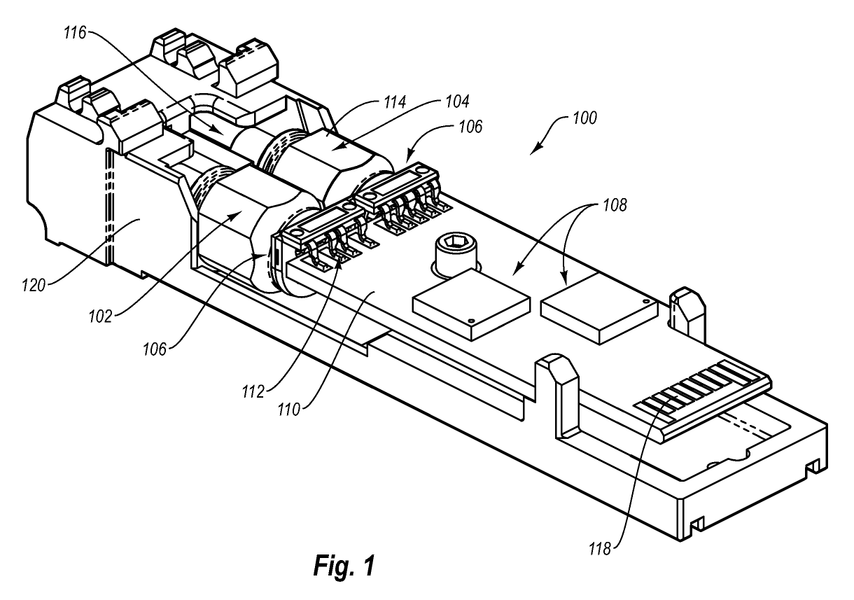

Reference is first made to FIG. 1, which discloses an optoelectronic transceiver module 100 for use in transmitting and receiving optical signals in connection with a host device (not shown). The optoelectronic transceiver module 100 includes various components, including a receiver optical subassembly (“ROSA”) 102, a transmitter optical subassembly (“TOSA”) 104, electrical interfaces 106, various electronic components 108, and a printed circuit board (“PCB”) 110. The two electrical interfaces 106 are used to electrically connect the ROSA 102 and the TOSA 104 to a plurality of conductive pads 112 located on the PCB 110. The electronic components 108 are also operably attached to the PCB 110.

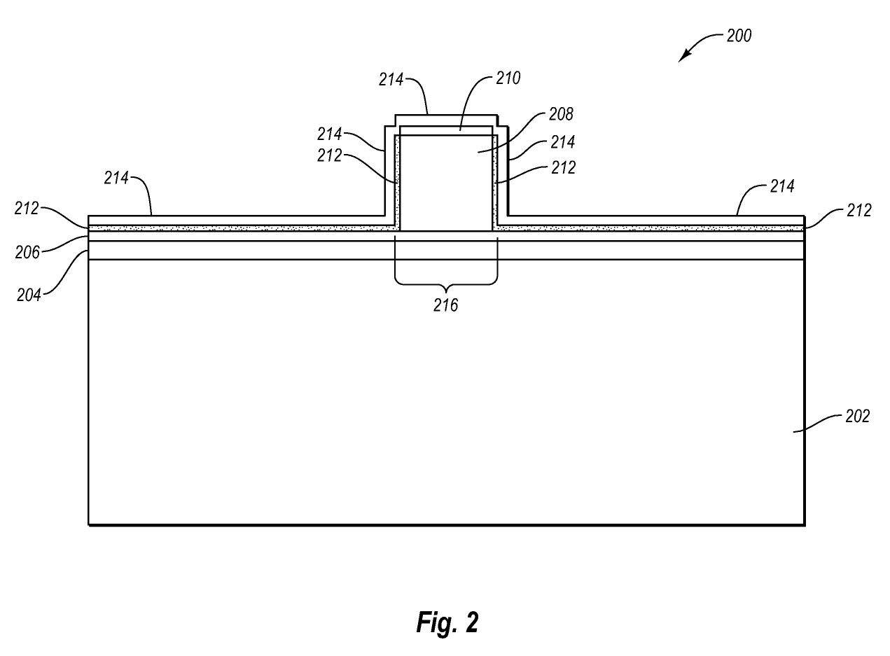

The TOSA 104 of the optoelectronic transceiver module 100 includes an optical transmitter, such as a RWG laser configured according to example embodiments of the present invention, as disclosed below in connection with FIG. 2. The TOSA 104 includes a barrel 114 within which a RWG laser is at least partially disposed. The TOSA 104 also includes a port 116 defined by the barrel 114 and configured to optically connect the RWG laser with a fiber-ferrule.

With continued reference to FIG. 1, an edge connector 118 is located on an end of the PCB 110 to enable the optoelectronic transceiver module 100 to electrically interface with a host device (not shown). As such, the PCB 110 facilitates electrical communication between the ROSA 102 and the TOSA 104, and the host device. In addition, the above-mentioned components of the optoelectronic transceiver module 100 are partially housed within a shell 120. The shell 120 can cooperate with a housing (not shown) to define an enclosure for components of the optoelectronic transceiver module 100.

The optoelectronic transceiver module 100 can be configured for optical signal transmission and reception at a variety of data rates including, but not limited to, 1 Gbps, 2 Gbps, 2.5 Gbps, 4 Gbps, 8 Gbps, 10 Gbps, 40 Gbps, 100 Gbps, or higher. Furthermore, the optoelectronic transceiver module 100 can be configured for optical signal transmission and reception at various nominal wavelengths including, but not limited to, 850 nm, 1310 nm, 1470 nm, 1490 nm, 1510 nm, 1530 nm, 1550 nm, 1570 nm, 1590 nm, 1610 nm, or any other any wavelength between about 800 nm and about 1650 nm. Actual wavelengths may vary from the nominal, in some instances by a +/−10 nm band. In addition, although one example of the optoelectronic transceiver module 100 is substantially compliant with the XFP Multi-Source Agreement (“MSA”), the optoelectronic transceiver module 100 can alternatively be substantially compliant with one of a variety of different MSAs, but not limited to, the SFP MSA or the SFF MSA. Further, example RWG lasers disclosed herein can be employed in optoelectronic transponder modules.

In operation, the optoelectronic transceiver module 100 receives electrical signals from a host device (not shown) to which the optoelectronic transceiver module 100 is operably connected. The electrical signals are received by the edge connector 118 of the PCB 110, transmitted through the PCB 110 and one of the electrical interfaces 106, and finally to the TOSA 104. Circuitry of the optoelectronic transceiver module 100 then drives a RWG laser within the TOSA 104 with signals that cause the TOSA 104 to emit optical signals corresponding to the electrical signals provided by the host. Accordingly, the TOSA 104 serves as an electro-optic transducer.

Further, the ROSA 102 receives optical signals from an optical fiber (not shown) operably connected to the optoelectronic transceiver module 100. The ROSA 102 includes an optical receiver, such as a photodiode, which converts the optical signals to electrical signals. The electrical signals are then transmitted through one of the electrical interfaces 106, the PCB 110, and the edge connector 118 of the PCB 110, and finally to a host device (not shown) to which the optoelectronic transceiver module 100 is connected. Accordingly, the ROSA 102 also serves as an electro-optic transducer.

The example combination of the optoelectronic transceiver module 100 and the TOSA 104 disclosed in FIG. 1 is only one of various architectures in which the principles of the present invention may be employed. The principles of the present invention are therefore not intended to be limited to any particular environment.

### 2. Example RWG Laser

Together with FIG. 1, reference is now made to FIG. 2. FIG. 2 discloses aspects of one example of a RWG laser denoted generally at 200. The RWG laser 200 disclosed in FIG. 2 is implemented as either a distributed feedback (“DFB”) RWG laser or a Fabry-Perot (“FP”) RWG laser. It should be noted, however, that the principles of the present invention can be extended more generally to other edge-emitting laser types, including other RWG lasers where protective and/or passivation layers are employed. In addition, the principles of the present invention can also be extended more generally to other edge-emitting lasers such as buried heterostructure lasers and, in some embodiments, to surface emitting lasers.

As disclosed in FIG. 2, the RWG laser 200 includes a substrate 202, a multiple quantum well (“MQW”) active layer 204 disposed above the substrate 202, a semiconductor spacer layer 206 disposed above the active layer 204, and a ridge structure 208 disposed above the semiconductor spacer layer 206. It is noted that the ridge structure 208 is not limited to the substantially rectangular shape disclosed in FIG. 2. For example, the ridge structure 208 can have a trapezoidal shape or it may have rounded corners at the top or bottom. The RWG laser 200 also includes a contact layer 210 disposed above the ridge structure 208. The RWG laser 200 may also include a bottom contact layer (not shown) that is applied to the substrate 202. In some example embodiments, one or more of the layers 204 to 210 is epitaxially grown.

It is noted that in some example embodiments, the semiconductor spacer layer 206 may be considered to be part of the active layer 204. For example, when the semiconductor spacer layer 206 is grown from a quaternary material, the semiconductor spacer layer 206 may properly be considered part of the active layer 204. Therefore, it is understood that the semiconductor spacer layer 206 is optional as its function may be accomplished by a layer more properly considered to be part of the active layer 204.

In addition, the RWG laser 200 includes a dielectric passivation layer 212 disposed above the semiconductor spacer layer 206 and extending along either side of the ridge structure 208 such that the passivation layer 212 is in substantial contact with each side of the ridge structure 208. Further, the RWG laser 200 includes a top metallic contact layer 214 disposed above both the dielectric passivation layer 212 and the contact layer 210 and layered alongside the portions of the dielectric passivation layer 212 that contact the sides of the ridge structure 208. In general, the passivation layer 212 separates the ridge structure 208 from the top metallic contact layer 214 except in the region of the top and upper sides of the ridge structure 208. Different arrangements may be employed for different laser types. The top metallic contact layer 214 is composed of one or more metal or metal alloy layers including, for example, titanium, platinum and gold. In one embodiment, each of the layers 212-214 is non-epitaxially grown layers of the RWG laser 200.

In operation, an optical signal is produced at an active region 216 of the active layer 204 and output from the active region 216 at one end facet (not shown) of the RWG laser 200. As disclosed in FIG. 2, the active region 216 of the RWG laser 200 is narrower than the active layer 204. In particular, the active region 216 of the active layer 204 is restricted to the dimensions defined by the lateral dimensions and position of the ridge structure 208. In other lasers, however, the active region may be larger or smaller than the active region 216.

The dielectric passivation layer 212 electrically isolates the RWG laser 200 by preventing current applied to the top metallic contact layer 214 from penetrating the ridge structure 208 except at the top of the ridge structure 208. This restricts the current to the region immediately beneath the ridge structure 208 which results in lasing. The dielectric passivation layer 212 also prevents humidity or other contamination from entering the interior of the RWG laser 200. In addition, the dielectric passivation layer 212 can reduce parasitic capacitance that may undesirably affect operation of the RWG laser 200.

In addition, the dielectric passivation layer 212 is also configured to reduce or eliminate the tensile strain imposed on the active region 216 by the top metallic contact layer 214. More particularly, the dielectric passivation layer 212 can be composed of a material that is compressively strained. In general, forming the dielectric passivation layer 212 from a compressively strained material can reduce or eliminate the external tensile strain imposed on the ridge structure 208 by the top metallic contact layer 214 and/or other structures. This reduction in, or elimination of, the net tensile strain on the ridge structure 208 can in turn reduce or eliminate the tensile strain that is propagated or transmitted from the ridge structure 208 through the semiconductor spacer layer 206 to the active region 216.

In one example embodiment, the dielectric passivation layer 212 is formed from a material that exhibits compressive strain. For example, the dielectric passivation layer 212 can be formed from silicon dioxide (SiO₂) that has been fabricated in such a way as to exhibit compressive strain. This compressive strain can serve to substantially cancel out the net tensile strain of external tensile strain contributors, such as the top metallic contact layer 214, resulting in a net zero, or nearly zero, total strain propagated or transmitted through the ridge structure 208 and the semiconductor spacer layer 206 to the active region 216. By reducing or neutralizing tensile strain, the compressive strain of the dielectric passivation layer 212 reduces the likelihood of cracking or other strain-related damage in the active region 216, thereby potentially reducing damage or failure in the RWG laser 200. In some example embodiments, the strain is minimized at the point where the dielectric passivation layer 212 meets the semiconductor spacer layer 206, and particularly in the lower corners where the sides of the ridge structure 208 meet the upper surface of the semiconductor spacer layer 206.

In some example embodiments, it is possible to use fewer or more layers in the RWG laser 200 than what are disclosed in FIG. 2. For instance, the active layer 204 can be a composite layer made up of multiple layers. In one particular example, the active layer may include a composite layer made up of separate confinement heterostructure (“SCH”) layers and may include one or more quantum wells.

The example embodiments disclosed herein are to be considered in all respects only as illustrative and not restrictive.

What is claimed is:

1. A ridge waveguide (RWG) laser comprising:
a substrate;
an active layer disposed above the substrate;
a ridge structure disposed above the active layer;
a contact layer disposed above the ridge structure;
a compressively strained dielectric passivation layer disposed above the active layer and extending along either side of the ridge structure such that the passivation layer is in substantial contact with each side of the ridge structure; and
a top metallic contact layer disposed above both the dielectric passivation layer and the contact layer and layered alongside the portions of the dielectric passivation layer that contact the sides of the ridge structure.

2. The RWG laser as recited in claim 1, wherein the compressively strained dielectric passivation layer comprises a compressively strained silicon dioxide layer.

4. The RWG laser as recited in claim 1, wherein the RWG laser is a distributed feedback laser or as a Fabry-Perot laser.

5. The RWG laser as recited in claim 1, wherein the RWG laser is configured for optical signal transmission at about 10 Gbps and about 1310 nm.

6. The RWG laser as recited in claim 1, further comprising a semiconductor spacer layer disposed between the active layer and the ridge structure.

7. The RWG laser as recited in claim 6, wherein there is substantially no net external tensile strain imposed on the ridge structure by the combination of the compressively strained dielectric passivation layer and the top metallic contact layer at a lower corner where the ridge structure meets the semiconductor spacer layer.

8. A transmitter optical sub-assembly (TOSA) comprising:
a barrel that defines a port;
a RWG laser at least partially disposed within the barrel, the port configured to optically connect the RWG laser with a fiber-ferrule, the RWG laser comprising:
a substrate;
an active layer disposed above the substrate;
a ridge structure disposed above the active layer;
a contact layer disposed above the ridge structure;
a compressively strained dielectric passivation layer disposed above the active layer and extending along either side of the ridge structure such that the passivation layer is in substantial contact with each side of the ridge structure; and
a top metallic contact layer disposed above both the dielectric passivation layer and the contact layer and layered alongside the portions of the dielectric passivation layer that contact the sides of the ridge structure.

9. The TOSA as recited in claim 8, wherein the compressively strained dielectric passivation layer comprises a compressively strained silicon dioxide layer.

10. The TOSA as recited in claim 8, wherein the RWG laser is a distributed feedback laser or as a Fabry-Perot laser.

11. The TOSA as recited in claim 8, wherein the RWG laser is configured for optical signal transmission at about 10 Gbps and about 1310 nm.

12. The TOSA as recited in claim 8, wherein the active layer comprises:
a multiple quantum well layer; and
a semiconductor spacer layer grown from a quaternary material.

13. The TOSA as recited in claim 8, wherein there is substantially no net external tensile strain imposed on the ridge structure by the combination of the compressively strained dielectric passivation layer and the top metallic contact layer.

14. An optoelectronic transceiver module comprising:
a printed circuit board;
a receiver optical sub-assembly (ROSA) electrically connected to the printed circuit board;
a transmitter optical sub-assembly (TOSA) electrically connected to the printed circuit board, the TOSA comprising:
a barrel that defines a port;
a RWG laser at least partially disposed within the barrel, the port configured to optically connect the RWG laser with a fiber-ferrule, the RWG laser comprising:
a substrate;
an active layer disposed above the substrate;
a ridge structure disposed above the active layer;
a contact layer disposed above the ridge structure;
a compressively strained dielectric passivation layer disposed above the active layer and extending along either side of the ridge structure such that the passivation layer is in substantial contact with each side of the ridge structure; and
a top metallic contact layer disposed above both the dielectric passivation layer and the contact layer and layered alongside the portions of the dielectric passivation layer that contact the sides of the ridge structure.

15. The optoelectronic transceiver module as recited in claim 14, wherein the compressively strained dielectric passivation layer comprises a compressively strained silicon dioxide layer.

16. The optoelectronic transceiver module as recited in claim 14, wherein the optoelectronic transceiver module is substantially compliant with the XFP MSA, the SFP MSA, or the SFF MSA.

17. The optoelectronic transceiver module as recited in claim 14, wherein the RWG laser is a distributed feedback laser or as a Fabry-Perot laser.

18. The optoelectronic transceiver module as recited in claim 14, wherein the RWG laser is configured for optical signal transmission at about 10 Gbps and about 1310 nm.

19. The optoelectronic transceiver module as recited in claim 14, wherein the active layer comprises:
a plurality of separate confinement heterostructure layers; and
a semiconductor spacer layer grown from a quaternary material.

20. The optoelectronic transceiver module as recited in claim 14, wherein there is substantially no net external tensile strain imposed on the ridge structure by the combination of the compressively strained dielectric passivation layer and the top metallic contact layer.
